(19) United States
(12) Patent Application Publication
(10) Pub. No.: US 2026/0317159 A1
(43) Pub. Date: Oct. 15, 2026

(54) COATING FOR REDUCTION OF DEVICE MECHANICAL AND/OR ELECTRICAL FATIGUE

(71) Applicant: The Charles Stark Draper Laboratory, Inc., Cambridge, MA (US)

(72) Inventors: Joshua Javor, Cambridge, MA (US); William Clower, Cambridge, MA (US); Jonathan J. Bernstein, Cambridge, MA (US)

(73) Assignee: The Charles Stark Draper Laboratory, Inc., Cambridge, MA (US)

(21) Appl. No.: 19/646,510

(22) Filed: Apr. 13, 2026

Related U.S. Application Data
(60) Provisional application No. 63/788,757, filed on Apr. 14, 2025.

(51) Int. Cl. B81B 3/00

(52) U.S. Cl. CPC B81B 3/0072; B81B 2203/0118

(57) ABSTRACT

A micro-electro-mechanical systems (MEMS) device may include one or more coating layers to improve mechanical and/or electrical resilience. A MEMS device may include a semiconductor substrate and a first coating layer and a second coating layer that are on the semiconductor substrate. The first coating layer may cover at least a portion of a surface of the semiconductor substrate. The second coating layer may cover at least a portion of the first coating layer. A MEMS device may include a support and a MEMS component coupled to the support that is displaceable in response to applied force and includes an electrode. The MEMS component may include a semiconductor substrate and a coating layer on a surface of the semiconductor substrate.

### RELATED APPLICATIONS

This application claims the benefit under 35 U.S.C. § 119 (e) of U.S. Provisional Patent Application Ser. No. 63/788,757, filed Apr. 14, 2025, under Attorney Docket No.: C1756.70051US00, and entitled, “COATING FOR REDUCTION OF DEVICE MECHANICAL STRESS,” which is incorporated by reference herein in its entirety.

### BACKGROUND

Micro-electromechanical systems (MEMS) integrate electrical and mechanical components fabricated using semiconductor processing techniques (e.g., photolithography, thin-film deposition, and etching) at feature dimensions ranging from sub-micron to several hundred microns. MEMS devices have been widely adopted in consumer electronics, automotive systems, biomedical instrumentation, and telecommunications.

### SUMMARY

Some aspects of the present disclosure relate to a micro-electro-mechanical systems (MEMS) device, including: a semiconductor substrate; and a first coating layer and a second coating layer that are on the semiconductor substrate, wherein the first coating layer covers at least a portion of a surface of the semiconductor substrate, and wherein the second coating layer covers at least a portion of the first coating layer.

In some embodiments, the first coating layer and the semiconductor substrate have a Young's modulus within 5% of each other.

In some embodiments, the first coating layer has a first coefficient of thermal expansion, the second coating layer has a second coefficient of thermal expansion, and the second coefficient of thermal expansion is closer than the first coefficient of thermal expansion to a coefficient of thermal expansion of the semiconductor substrate.

In some embodiments, the first coating layer includes silicide and the second coating layer includes a transition metal.

In some embodiments, the first coating layer includes silicide and the semiconductor substrate includes at least a portion of the silicide below the surface.

In some embodiments, the first coating layer is configured to distribute stress localized on a region of the semiconductor substrate over a larger area of the semiconductor substrate than without the first coating layer.

In some embodiments, the first coating layer is disposed at least in part within a crack in the surface of the semiconductor substrate.

In some embodiments, the first coating layer and/or the second coating layer includes electrically conductive material.

In some embodiments, the MEMS device includes an electrode coupled to the semiconductor substrate, and the electrically conductive material of the first coating layer and/or the second coating layer is electrically isolated from the electrode.

In some embodiments, the first coating layer and/or the second coating layer has a thickness between 0.1 nanometers (nm) and 500 nm.

Some aspects of the present disclosure relate to a micro-electro-mechanical systems (MEMS) device, including: a support; and a MEMS component coupled to the support that is displaceable in response to applied force and includes an electrode, wherein the MEMS component includes a semiconductor substrate and a coating layer on a surface of the semiconductor substrate.

In some embodiments, the coating layer is disposed at least in part within a crack in the surface of the semiconductor substrate.

In some embodiments, the coating layer includes electrically conductive material that is electrically isolated from the electrode.

In some embodiments, the coating layer includes silicide and the semiconductor substrate includes at least a portion of the silicide below the surface.

In some embodiments, the coating layer is a first coating and the MEMS device further includes a second coating on the first coating, and the second coating includes metal.

In some embodiments, the second coating includes tungsten.

In some embodiments, the coating layer has a thickness between 0.1 nanometers (nm) and 500 nm.

In some embodiments, the coating layer and the semiconductor substrate have a Young's modulus within 5% of each other.

Some aspects of the present disclosure relate to a MEMS-based gyroscope including the MEMS device, wherein the MEMS component includes a rotor, a flexure, and/or a mass.

Some aspects of the present disclosure relate to a MEMS-based sensor system including the MEMS device and circuitry electrically coupled to the electrode and configured to drive the MEMS device with an oscillating drive signal.

### BRIEF DESCRIPTION OF DRAWINGS

Various aspects and embodiments will be described herein with reference to the following figures. It should be appreciated that the figures are not necessarily drawn to scale. Items appearing in multiple figures are indicated by the same or similar reference number in all the figures in which they appear.

FIG. 1A is a schematic side view of a first example micro-electromechanical systems (MEMS) device including coating layers, according to some embodiments.

FIG. 1B is a schematic side view of a second example MEMS device including coating layers, according to some embodiments.

FIG. 1C is a cross section of a component of a MEMS device illustrating a plurality of coating layers, according to some embodiments.

FIG. 2 is a flow chart illustrating an example method for fabricating a MEMS device, according to some embodiments.

FIG. 3 is a scanning electron microscopy (SEM) micrograph of a MEMS flexure with damage to the flexure identified, according to some embodiments.

FIG. 4A is top view of a notch resonator (Nr), according to some embodiments.

FIG. 4B is an analytical model of the Nr device of FIG. 4A indicating localized stress of a microcrack in the surface of the Nr, according to some embodiments.

FIG. 5 is an SEM micrograph of multilayer coatings of silicon wells, according to some embodiments.

FIG. 6A is a Von Mises stress graph of a two-dimensional model of a flexure built-in at a supported end and torque applied at an opposite free end, with a surface crack included in the top and bottom surfaces, according to some embodiments.

FIG. 6B is a magnified view of the surface crack of the simulated flexure of FIG. 6A with the lines illustrating the original position of the flexure prior to the application of the torque, according to some embodiments.

FIG. 6C is a graph illustrating the stress concentration factor versus depth/width ratio of the surface crack of FIG. 6B, according to some embodiments.

FIG. 6D is a magnified view of the surface crack of FIG. 6A on a simulated flexure having a palladium silicide (PdSi) coating layer having torque applied thereto, according to some embodiments.

FIG. 7A is a top view of a tuning fork resonator (TFr), according to some embodiments.

FIG. 7B is a perspective view of the TFr of FIG. 7A undergoing laser Doppler vibrometry (LDV), according to some embodiments.

FIG. 7C is a side cross-sectional view of a mass of the TFr of FIGS. 7A-7C, according to some embodiments.

FIG. 8A is a graph of optical measurements of surface bias of the TFr of FIGS. 7A-7C, according to some embodiments.

FIG. 8B is a graph of measurements of MEMS modes of the TFr of FIGS. 7A-7C, according to some embodiments.

FIG. 8C is a graph of quality (Q) factor measurements of the TFr of FIGS. 7A-7C, according to some embodiments.

FIG. 8D is a graph of out of plane Q-factor of the TFr 700 of FIGS. 7A-7C over varying chamber pressure, according to some embodiments.

FIG. 9 is top view of a vibrating wheel resonator (VWr), according to some embodiments.

The features and advantages of the present disclosure will become more apparent from the detailed description set forth below when taken in conjunction with the drawings. When describing embodiments in reference to the drawings, directional references (“above,” “below,” “top,” “bottom,” “left,” “right,” “horizontal,” “vertical,” etc.) may be used. Such references are intended merely as an aid to the reader viewing the drawings in a normal orientation. These directional references are not intended to describe a preferred or only orientation of features of an embodied device. A device may be embodied using other orientations.

### DETAILED DESCRIPTION

The present disclosure provides novel micro-electromechanical systems (MEMS) devices, such as resonators with improved performance drift (e.g., <1%) over an extended time period (e.g., >10 years). In some embodiments, approaches described herein involve coating layers (e.g., single layers or multilayers) configured to combat effects of mechanical and/or electrical aging. MEMS devices (e.g., Silicon-MEMS devices) may be coated with ultra-thin, durable materials that are electrically conductive to produce mechanically stable devices with extended lifetimes that are not as affected by dielectric charging as in prior approaches. Some examples of the present disclosure provide a MEMS device comprising a semiconductor substrate (e.g., silicon substrate) may have coating layers (e.g., first coating layer and a second coating layer) on the substrate. According to some embodiments, the first coating layer covers at least a portion of a surface of the semiconductor substrate and the second coating layer covers the first coating layer. Some examples of methods described herein involve depositing (e.g., via atomic layer deposition (ALD)) coating layers (e.g., a first coating layer) on a semiconductor substrate (e.g., a silicon substrate).

MEMS-based systems, such as MEMS-based inertial sensor systems that facilitate navigation in GPS-denied applications, are being demanded to perform over longer lifetimes and in harsher environments. As MEMS devices have been developed with improved sensitivity and stability, larger, alternative sensor arrangements in many applications have been replaced with MEMS devices. The smaller size, weight, power, and cost of MEMS devices have allowed a myriad of new missions and applications, such as handheld navigation in GPS-denied environments or compact self-guided devices.

A MEMS-based inertial sensor system typically includes a semiconductor device having parts that move with respect to one another in response to acceleration, and the moving parts provide an electrical response indicative of the acceleration. Over time, mechanical deterioration of the moving parts results in bias (e.g., drift) in the electrical response of the system, which reduces accuracy and eventually renders the system unusable at the end of its life. It is further recognized that the system may exhibit electrical deterioration through buildup of trapped charges in dielectric materials (e.g., oxide layers) that bias the system's electrical response. Application of MEMS devices would benefit from greater bias stability (e.g., navigation accuracy) in harsher environments and/or over longer durations of aging.

The present disclosure recognizes that mechanical fatigue due to subtle defects contributes significantly to mechanical deterioration of a MEMS-based system. Some devices generally do not have perfectly straight or smooth sidewalls (e.g., as fabricated), and mechanical stresses over time or heavy use can cause cracks to form or propagate, resulting in drifting resonant mode frequency, reduction in quality factor, and ultimately sensor bias. The present disclosure recognizes that oxidation of a semiconductor (e.g., silicon) surface may cause additional stress from oxide thickening, as has been observed in polysilicon. The present disclosure further recognizes that oxide formation in minor (e.g., subcritical) cracks may have a wedging effect on an already cracked surface, as has been further observed in polysilicon. The present disclosure further recognizes that displacement of moving parts of a MEMS-based system can result in dislocation effects in the semiconductor (e.g., silicon) structure, as has been observed in single-crystal silicon.

To mitigate mechanical fatigue, the present disclosure provides techniques for coating resonators with mechanically stable and smooth coating layers, which may distribute stress around subtle defects and thereby limit aging-driven sensor drift. In some embodiments, a MEMS device may include a semiconductor substrate having a coating layer thereon, the coating layer being configured to limit stress concentration on at least a portion of the semiconductor substrate. For example, the coating layer may cover at least the portion of the semiconductor substrate, so as to be disposed at least in part within a crack in the semiconductor substrate. In some embodiments, the coating layer may have a Young's modulus similar to the semiconductor substrate, facilitating distribution of stress via the coating layer over a larger portion of the semiconductor substrate than without the coating layer.

The present disclosure further recognizes that sensor bias can result from surface charging (e.g., dielectric charging) on surfaces of (e.g. silicon) MEMS structures. Charges may accumulate and become trapped within a semiconductor oxide layer (e.g., silicon dioxide) while an electric field is being applied to the MEMS structure, forming an electret with a transient lifetime. For example, native oxide growth on Si-MEMS devices, even at thicknesses <10 angstroms (Å) may cause significant charging of the MEMS device surface. Built-in voltages produced from these charging effects may create extraneous forces that may lead to significant variations in performance parameters such as bias drift and resonant frequency shifting. Charge accumulation may create enough instability (e.g., bias drift) that MEMS devices may fail during long-term or short-term missions (e.g., space exploration missions), even without significant mechanical stress. Dielectric charging may occur during normal operation, and may be enhanced from external sources such as exposure to radiation.

To mitigate effects of dielectric charging, a MEMS device may include a semiconductor substrate having a coating layer that is electrically conductive and/or includes an electrically conductive material (e.g., tungsten). By including an electrically conductive coating layer, surface charging may be reduced or eliminated.

Further, the present disclosure provides multi-layer coating layers that may be configured to synergize to protect a MEMS device against mechanical and electrical fatigue. For example, a semiconductor substrate may have a first coating layer and a second coating layer on the first coating layer, which may be configured to synergistically limit mechanical and electrical fatigue, respectively. For example, the first coating layer and the second coating layer may include different materials. For example, the first coating layer may be disposed at least in part within cracks and/or limit stress concentration on the semiconductor substrate, such as by being thin and having a similar Young's modulus to the semiconductor substrate. The second coating layer (and/or the first coating layer) may be electrically conductive to limit surface charge buildup. Alternatively or additionally, the second coating layer may have a lower coefficient of thermal expansion than the first coating layer so as to constrain thermal expansion of the first coating layer that may mismatch with respect to the semiconductor substrate.

In some embodiments, MEMS devices may be fabricated from wafers using a subtractive process, which may result in a single integral semiconductor substrate, but the present disclosure is not limited thereto. According to various embodiments, different deposition methods may be used to deposit coating layers on a semiconductor substrate. In some embodiments, atomic layer deposition (ALD) is used to deposit coatings (e.g., metal silicides, ruthenium, tungsten). Other deposition methods may be used, such as, for example, chemical vapor deposition, physical vapor deposition, or the like. In some embodiments, the deposition method includes high-density plasma enhanced chemical vapor deposition (HDPCVD) to deposit any of a variety of coating layers (e.g., silicon carbide, diamond-like carbon).

The present disclosure describes some devices where MEMS devices may be implemented, however, it should be understood that other devices are possible. For example, in one set of embodiments, the MEMS device may be a first MEMS component within a gyroscope having more than one MEMS component. The MEMS device may have one or more MEMS components, such as for example, a first MEMS component comprising the semiconductor substrate and first coating layer and second coating layers and a second MEMS component configured to move relative to the first MEMS component in response to an applied force. In some embodiments, the MEMS device may be configured as a MEMS sensor (e.g., inertial sensor).

The MEMS device may be a component of a gyroscope, an accelerometer, a magnetometer, or the like. It should be understood that the MEMS device is not limited to these devices.

In some embodiments, the MEMS device described herein may be a sensor (e.g., inertial sensors). The sensor may be implemented in an accelerometer, gyroscope, and other electronics. The semiconductor within the MEMS device may include a single-crystal/monocrystalline MEMS or a polycrystalline MEMS.

The MEMS device may be configured to operate as a standalone device for many applications. However, in some cases, a system having a MEMS device may configured to operate together or in parallel with other devices for a variety of reasons. For example, a system may include a MEMS gyroscope and a MEMS resonator. Together with the resonator designs, the system can utilize a phase locked loop with automatic gain control to enable stable oscillation amplitude and precise frequency tracking.

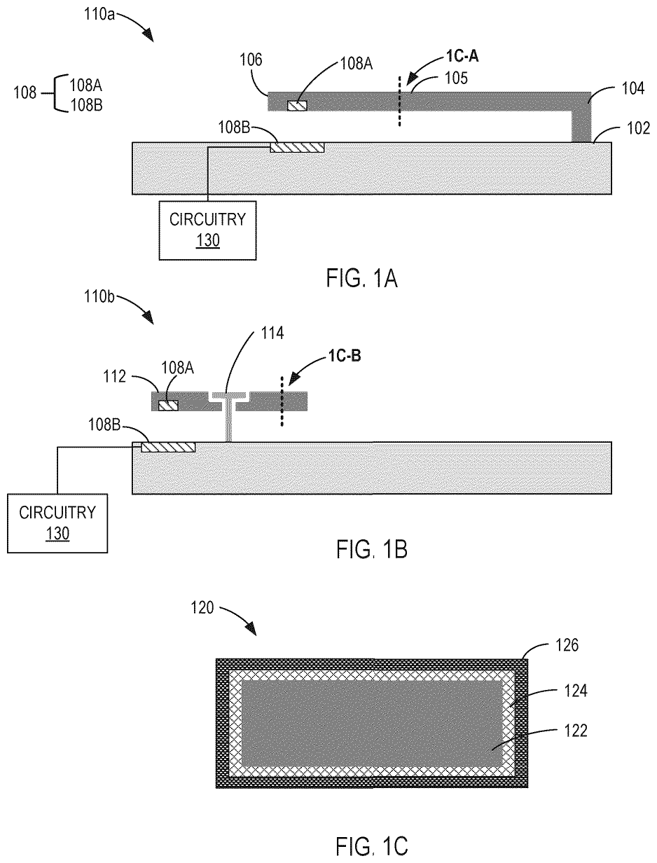

FIGS. 1A-1C are schematic side views of example MEMS devices including coating layers, according to some embodiments.

FIG. 1A shows a first example MEMS device 110a including a support 102 on which an arm 104 is disposed. For example, the arm 104 may be a sensor disposed on the support 102 and configured to sense acceleration. In such examples, the arm 104 may include an extended feature configured to be displaced with respect to the support 102 to indicate a measurement of pressure and/or vibrations. For instance, a free end 106 of the arm 104 may be configured to displace in response to applied force, inducing a mechanical deflection and/or strain in the sensor that indicates the pressure differential or vibration. While only one arm is shown in FIG. 1A, it should be appreciated that multiple arms may be included, such as to provide a differential sensing mode as described further herein.

In some embodiments, the MEMS device 110a may be configured to provide an electrical response indicating deflection of the arm 104. For example, the electrical response may be provided using one or more electrodes coupled to the support 102 and/or the arm 104. For instance, the electrode(s) may be configured to transduce deflection of the arm 104 into an electrical output signal representative of the magnitude and frequency of the pressure differential and/or vibration. In some embodiments, an impedance (e.g., capacitance, resistance, inductance) and/or piezoelectric resonance between the first and second electrode may indicate displacement of the arm 104.

In some embodiments, electrodes 108 may be coupled to the support 102 and/or arm 104. For example, a first electrode 108A may be coupled to the free end 106 of the arm 104 and a second electrode 108B may be coupled to the support 102 proximate (e.g., beneath) the free end 106. For instance, one or both of the electrodes 108 may be configured to receive a bias signal and/or one or both of the electrodes 108 may be configured to indicate displacement of the arm 104 in a response to the bias signal, such as in an impedance measured using the bias signal.

In some embodiments, the MEMS device 110a may be included in a sensor, such as an inertial sensor. For example, the arm 104 may be configured to displace in response to force, such as due to gravitational acceleration acting on a body on which the sensor is placed. In some embodiments, the arm 104 and/or support 102 may include electrodes 108 configured to sense displacement indicative of applied force. For instance, circuitry 130 circuitry may be electrically coupled to the one or more of the electrode 108 and configured to drive the MEMS device 110a with an oscillating drive signal. In some embodiments, circuitry 130 may be configured to determine displacement of the arm 104 relative to the support 102 based on electrical response between the electrodes 108, such as using a change of measured impedance (e.g., resistance, capacitance, and/or inductance). In some embodiments, circuitry 130 may be configured to interrogate the electrodes 108 with a bias signal and measure the impedance in response to interrogation with the bias signal. In some embodiments, different sets of electrodes 108 may be included for interrogation with a bias signal and for measuring electrical response, respectively.

In some embodiments, the first example MEMS device 110a may have a coating layer. In some embodiments, the arm 104 and/or support 102 may have the coating layer. In other embodiments, only the arm 104 or the support 102 may have the coating layer. In some embodiments, the support 102 and/or the arm 104 may be partially covered with the coating layer. For example, regions of the arm 104 that may be subject to localized stress and/or strain may be covered with a coating layer. For example, a coating layer may be on a pivot region 105 about which a free end 106 of the arm 104 moves in response to applied force. For instance, the coating layer may reinforce the pivot region 105 to withstand displacement of the free end 106 about the pivot region 105 during operation. For example, as described further herein, a coating layer may be at least partially disposed within cracks in the arm 104 that may deteriorate under localized stress, and/or a coating layer may be configured to spread stress localized on the pivot region 105 over a larger area than just the pivot region 105. Alternatively or additionally, a coating layer may be electrically conductive so as to reduce or eliminate dielectric surface charging of arm 104 and/or support 102. For example, such a coating layer may be electrically isolated from the electrodes 108 so as to avoid short-circuiting the electrodes 108 to each other and/or other components. For instance, the coating layer may be etched or otherwise not present in an area proximate the electrodes 108, and/or an insulating layer may be added therebetween. In some embodiments, the support 102 and/or arm 104 may have two or more layers of coating. For example, as described further herein, multiple coating layers may synergize to combat mechanical and/or electrical fatigue.

FIG. 1B illustrates an example 3-level MEMS device 110b including a rotor 112 coupled to a support 102 (e.g., as in FIG. 1A). In some embodiments, the rotor 112 may be a gear and/or disk rotatably coupled to the support 102 by a bearing 114. In some embodiments, the rotor 112 may be configured to rotate in response to applied force, such as described herein for the arm 104 in FIG. 1A. Though only one rotor 112 is shown in FIG. 1B, a MEMS device may include any number of rotors 112 depending on the implementation, such as to provide differential sensing. Some embodiments may include an arm and a rotor in combination, for example with electrodes on the arm and rotor, respectively, contributing to the electrical response.

The second example MEMS device 110b include a coating layer. In some embodiments, the support 102, rotor 112, and/or the bearing 114 may be covered by a coating layer. For example, parts of the rotor 112 that interface with the bearing 114, and/or vice versa, may be covered by a coating layer. In some embodiments, interfacing regions of the rotor 112 and/or bearing 114 may experience localized stress, and a coating layer thereon may be configured to distribute the stress over a larger region and/or at least in part within cracks that could be damaged by repeated localized stress. Alternatively or additionally, a coating layer on the device 110b may be electrically conductive so as to reduce and/or eliminate dielectric surface charge buildup. In some embodiments, multiple coating layers may be included so as to synergize and combat mechanical and/or electrical fatigue.

In some embodiments, the support 102 as shown in FIGS. 1A and 1B may include silicon and/or silicon oxide. In some embodiments, the support 102 may be a silicon-on-insulator (SOI) wafer.

FIG. 1C is a cross section 120 of a component of one of the MEMS devices 110a, 110b illustrating a plurality of coating layers 124, 126 on a semiconductor substrate 122, according to some embodiments. In some embodiments, the cross section 120 may be a cross section of the arm 104 of the MEMS device 110a taken at the dashed line labeled “1C-A”. In some embodiments, the cross section 120 may be a cross-section of the rotor 112 in the 2-level MEMS device 110a of FIG. 1B taken at the dashed line labeled “1C-B”.

In some embodiments, MEMS devices 110a, 110b may have a semiconductor substrate 122, such as within the support 102, arm 104, rotor 112, and/or bearing 114. For example, MEMS devices 110a, 110b may include integral components sharing the semiconductor substrate, such as the support 102 and arm 104, and/or the components may have separate semiconductor substrates. The cross section 120 includes a portion of semiconductor substrate 122 covered with a first coating layer 124 and a second coating layer 126 on the first coating layer 124.

In some embodiments, the first coating layer 124 and/or the second coating layer 126 may include a thin film, such as having a thickness on the order of a nanometer (nm), 10 nm, 100 nm, and/or a micron. For example, the first coating layer 124 and/or the second coating layer 126 may be significantly thinner than a thickness of a cross section of the semiconductor substrate 122. In some embodiments, the first coating layer 124 and/or the second coating layer 126 may have a nanoscale or sub-nanoscale thickness (e.g., between 0.1 nanometers (nm) and 500 nm). Example materials that may be included in the first coating layer 124 are carbon, diamond-like carbon, transition metal, metal silicide, nickel silicide, palladium silicide, platinum silicide, silicon carbide, a refractory metal, ruthenium, tungsten, and a doped semiconductor layer. Some example materials that may be included in the second coating layer 126 are transition metals and Group VI elements (e.g., tungsten). In some embodiments, a single coating layer (e.g., metal silicide) may be used, which may include any material listed above.

In some embodiments, the first coating layer 124 and/or the second coating layer 126 may be configured to limit mechanical and/or electrical fatigue of the semiconductor substrate 122. For example, the first coating layer 124 may be disposed at least in part within cracks in the semiconductor substrate 122, such as cracks that would otherwise potentially grow upon application of localized stress. For instance, the cracks may be tiny artifacts of an imperfect fabrication process that may take repeated wear and/or time to deteriorate. In other examples, the first coating layer 124 may be configured to fill cracks that form in semiconductor substrate 122 during operation, such as years after completion of the fabrication process.

In some embodiments, the first coating layer 124 has a Young's modulus that is the same or similar to the Young's modulus of the semiconductor substrate 122. For example, the first coating layer 124 may have a Young's modulus approximately between 130 Gigapascal (GPa) and 450 GPa. In some embodiments, the semiconductor substrate 122 has a Young's modulus that is substantially the same as a Young's modulus of the first coating layer 124 (e.g., within 5%). For example, where the first coating layer 124 and the semiconductor substrate 122 have the same or similar Young's moduli (e.g., within a certain range such as 5%), for example, to limit stress concentration in the MEMS device. For example, similar Young's modulus values may facilitate spreading of localized stress over a larger area of the semiconductor substrate 122 than without the first coating layer 124. In the same or another example, the same or similar Young's modulus values may inhibit delamination of the first coating layer 124 for improved longevity of the MEMS device.

In some embodiments, the first coating layer 124 may be electrically conductive and/or may include electrically conductive material. For example, electrical conductivity of the first coating layer 124 may reduce or eliminate dielectric surface charge buildup, such as by providing a conductive path for trapped charges to escape from the semiconductor substrate 122, which may reduce or eliminate resulting sensor bias from electrical aging.

In some embodiments, the first coating layer 124 may have a thermal expansion coefficient that is similar to the semiconductor substrate 122 (e.g., between 2 parts-per-meter per degree Kelvin (ppm/K) and 15 ppm/K). For example, the thermal expansion coefficient of the first coating layer 124 may be low for a MEMS device subject to high operating temperatures (e.g. >100° C.) such that the first coating layer 124 does not expand to a greater degree than the semiconductor substrate at high operating temperatures.

In some embodiments, the first coating layer 124 and the second coating layer 126 may synergize to limit mechanical fatigue and/or electrical fatigue of the semiconductor substrate 122. For example, like the first coating layer 124, the second coating layer 126 may have a suitable Young's modulus (e.g., at least 400 GPa) for spreading localized stress exerted on a region of the semiconductor substrate 122. In some embodiments, the second coating layer 126 may be configured to conform to the first coating layer 124 (e.g., a surface of the first coating layer 124), such as to fill cracks in the first coating layer 124 to support the first coating layer 124 in filling larger cracks in the semiconductor substrate 122. In some embodiments, the second coating layer 126 may be electrically conductive and/or may include electrically conductive material to reduce or eliminate dielectric surface charge buildup.

In some embodiments, the second coating layer 126 may be configured to constrain thermal expansion of the first coating layer 124. For example, the second coating layer 126 may have a lower thermal expansion coefficient than the first coating layer 124 and/or closer to the thermal expansion coefficient of the semiconductor substrate 122 than the first coating layer 124, which may help to prevent expansion of the first coating layer 124 away from the semiconductor substrate 122. For instance, the first coating layer 124 may include a material having a suitable Young's modulus and/or electrical conductivity even if its thermal expansion coefficient is substantially higher than that of the semiconductor substrate 122 by using the second coating layer 126 to constrain thermal expansion of the first coating layer 124.

While the cross section 120 includes multiple coating layers, it should be appreciated that fewer or greater numbers of coating layers may be included, such as a single coating layer or three or more coating layers.

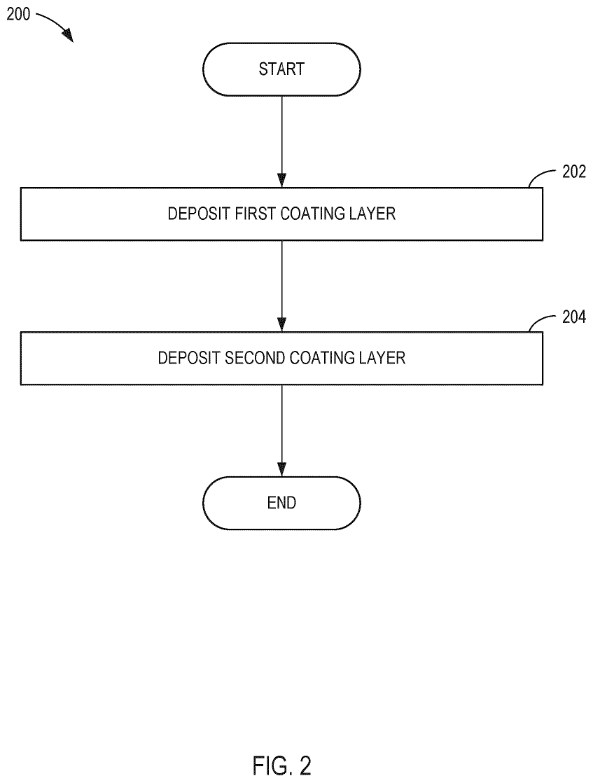

FIG. 2 is a flow chart illustrating an example method 200 for fabricating a coated MEMS device, according to some embodiments. In some embodiments, method 200 may be performed to manufacture a MEMS device such as shown in FIGS. 1A-1C.

As shown in FIG. 2, method 200 includes step 202 of depositing a first coating layer of a MEMS device and step 204 of depositing a first coating layer of a MEMS device. It should be appreciated that, in manufacturing a MEMS device having a single coating layer, one of steps 202 and 204 may be omitted. Moreover, in manufacturing a MEMS device having more than two coating layers, one or more of steps 202 and 204 may be repeated.

In some embodiments, step 202 may include depositing the first coating layer (e.g., 124 in FIG. 1C) on a semiconductor substrate (e.g., 122) of a MEMS device. For example, the first coating layer may be deposited on all or part of the semiconductor substrate, such as only on portions that will undergo localized stress during use.

In some embodiments, step 204 may include depositing the second coating layer (e.g., 126) on the semiconductor substrate (e.g., 122) of the MEMS device. For example, the second coating layer may be deposited on all or part of the semiconductor substrate, such as only on portions that will undergo localized stress during use.

In some embodiments, deposition in step 202 and/or 204 may include deposition of a thin film using CVD, plasma-enhanced CVD (PECVD), low-pressure CVD (LPCVD), high-density plasma chemical vapor deposition (HDPCVD), atomic layer deposition (ALD), physical vapor deposition (PVD), sputtering, and/or thermal evaporation. In some embodiments, multiple deposition processes may be used for one or each coating layer.

In some embodiments, method 200 may further include manufacturing components of the MEMS device, such as by an additive (e.g., deposition and/or bonding) and/or subtractive (e.g., patterning and/or etching) process. For example, manufacturing components of the MEMS device may be performed prior to step 202 and/or 204, such as where the coating layer(s) are selectively applied (e.g., using masking) to only a portion of the MEMS device once components have been formed. Alternatively or additionally, manufacturing components of the MEMS device may be performed after step 202 and/or 204, such as by depositing the coating layer(s) on the semiconductor substrate prior to patterning and etching the components. For instance, the coating layer(s) may be etched from any components of the MEMS device from which they are not to be included (e.g., to remove electrically conductive material that might short-circuit an electrode).

In some embodiments, patterning and etching the semiconductor substrate to fabricate components of the MEMS device may include application of structural and sacrificial thin films on top of the semiconductor substrate. For example, thin films may be applied using CVD, plasma-enhanced CVD (PECVD), low-pressure CVD (LPCVD), high-density plasma chemical vapor deposition (HDPCVD), atomic layer deposition (ALD), physical vapor deposition (PVD), sputtering, and/or thermal evaporation. Subsequent application of at least one thin film, the semiconductor substrate may be patterned via photolithography (e.g., ultraviolet (UV) photolithography, extreme ultraviolet (EUV) photolithography, or electron-beam exposure). A thin film may be subsequently etched to at least partially remove the thin films. Etching may be performed by wet etching (e.g., hydrofluoric acid (HF), potassium hydroxide (KOH), tetramethylammonium hydroxide (TMAH)), reactive ion etching (RIE), or deep reactive ion etching (DRIE).

In some embodiments, active regions of the MEMS device be doped via ion implantation or thermal diffusion.

In some embodiments, electrodes (e.g., 108) of the MEMS device (and/or electrical interconnects such as vias) may be formed in and/or on the semiconductor substrate by metallization using aluminum (Al), copper (Cu), titanium (Ti), or gold (Au).

In some embodiments, components formed by pattering and etching may be released by removing sacrificial thin films and leaving structural thin films. According to various embodiments, sacrificial thin films may be removed via HF vapor, wet HF, or xenon difluoride (XeF₂) gas-phase etching.

In some embodiments, method 200 may include manufacturing and/or preparing the semiconductor substrate for formation of a component and/or deposition of the coating layer(s). For example, the semiconductor substrate (e.g., including silicon, SOI, glass, quartz, and/or a polymer wafer) may undergo a surface treatment to form a dielectric isolation layer (e.g., silicon dioxide) at the surface of the semiconductor substrate. In some embodiments, the semiconductor substrate may undergo thermal oxidation (e.g., via dry thermal oxidation, wet thermal oxidation, or chemical vapor deposition (CVD)) to form an oxide coating (e.g., SiO₂). In some embodiments, the semiconductor substrate may undergo nitridation (e.g. via CVD) to form a silicon nitride (Si₃N₄).

In some embodiments, manufacturing a single-crystal semiconductor MEMS device includes fabricating a single-crystal silicon-on-insulator device layer, forming a wafer-level hermetic seal (e.g., in a controlled atmosphere or vacuum with getter). In some embodiments, through-Si Vias (TSVs) may be manufactured to provide electrical interconnects. In some embodiments, on-chip platinum temperature sensing resistors may be disposed on and/or in the MEMS device. In some embodiments, inner and outer polysilicon traces may be disposed for interconnect and out-of-plane sense/drive electrodes.

According to some embodiments, a MEMS system and/or device may be tested under certain conditions for mechanical and/or electrical performance over time and/or use. In some embodiments, the devices are aged and then tested. Testing conditions may include, for example, a vacuum chamber, a humidity chamber, or the like. As a non-limiting example, devices can be resonated in a vacuum chamber integrated with a laser vibrometer to monitor properties such as resonant frequency, damping and drift, as shown in the figure above.

In some embodiments, testing may be performed to analyze devices after exposure to a certain number of cycles and obtain information such as drift events and failure within the coating layers. According to some embodiments, microscopy techniques may be used to test the devices. For example, scanning electron microscopy (SEM) images of aged and failed devices can allow a comparison of experimental testing and computational simulations.

In some embodiments, the devices and systems described herein undergo accelerated aging testing for temperature, humidity, pressure, and/or vibration (e.g., according to International Electrical Code (IEC) 60068-2, IEC 60749-6, IEC 60068-3, IEC 60945). Aging analysis may be controlled through exposure to multiple cycles. For example, 10-year aging analysis of Cloaked and un-Cloaked devices may involve exposure of devices to at least 1 billion cycles performed at three temperatures (e.g., ambient, at least 150° C., at least 250° C.).

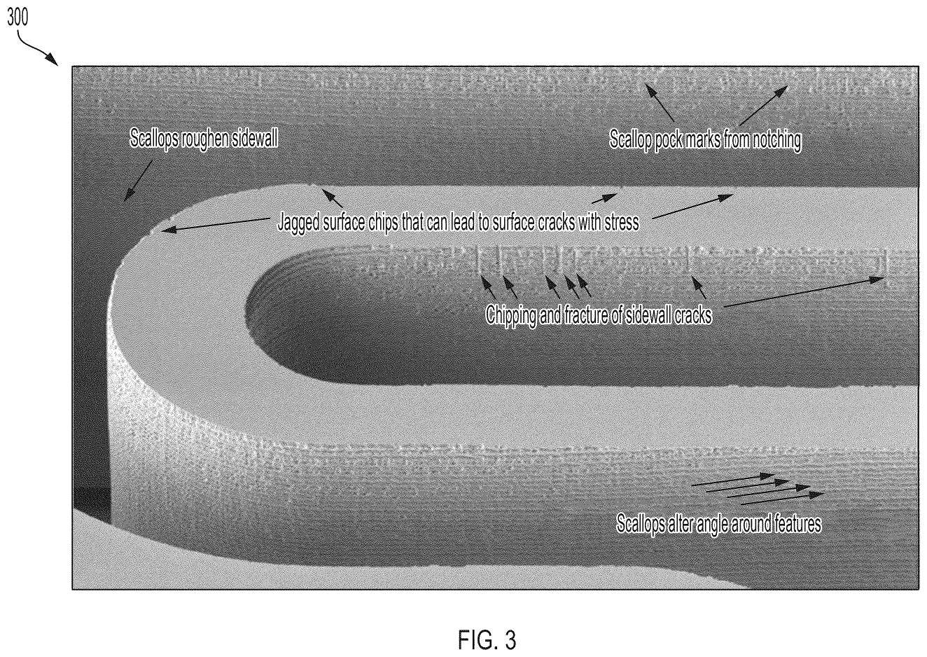

FIG. 3 is a scanning electron microscopy (SEM) micrograph of a MEMS flexure 300 with damage to the flexure 300 identified, according to some embodiments. The SEM micrograph of the MEMS flexure that depicts subtle vulnerabilities to sensor bias and drift with age.

In some embodiments, a MEMS device substrate may have cracks and/or scallops. For example, the fabrication process (e.g., method 200) may result in the formation of scallops along the surface of the components of the MEMS device, such as due to the layer-by-layer fabrication of the MEMS device. In some cases, the scallops may roughen sidewalls of MEMS components and alter angles around fabricated features. Between individual scallops, pocks can form in the sidewalls, leading to additional structural instabilities.

In some embodiments, fabrication defects such as chipping and fractures can compromise the structural integrity of the sidewalls. FIG. 3 shows some example defects on the MEMS flexure 300 (e.g., a pivot or interfacing point on which stress may be localized). Over time, vibrations and/or impact during operation may localize stress at these defects and increasingly compromise the structural integrity of the MEMS device.

The present disclosure recognizes that the strength of brittle materials may depend on the size distribution of the largest defects on the surface. For example, materials such as silicon-on-insulator (SOI) may be fabricated through processes that maintain low stress during fabrication and/or use dislocation-free single crystal silicon to limit risk of microcrack formation during aging. However, performance enhancement of bias stability may benefit from mitigation of extremely subtle defects that can form despite such careful fabrication processes.

In some embodiments, coating layers described herein (e.g., 124 and/or 126) may be configured to limit stress concentration on at least a portion of a MEMS device, such as the flexure 300. For example, coating layers described herein may be disposed at least in part within cracks, scallops, and/or pocks in a MEMS device, which may be present upon manufacture and/or may be formed through operation. In some embodiments, coating layers described herein may distribute localized stress over a greater area of a MEMS device, which may limit growth of cracks in the MEMS device over time and use.

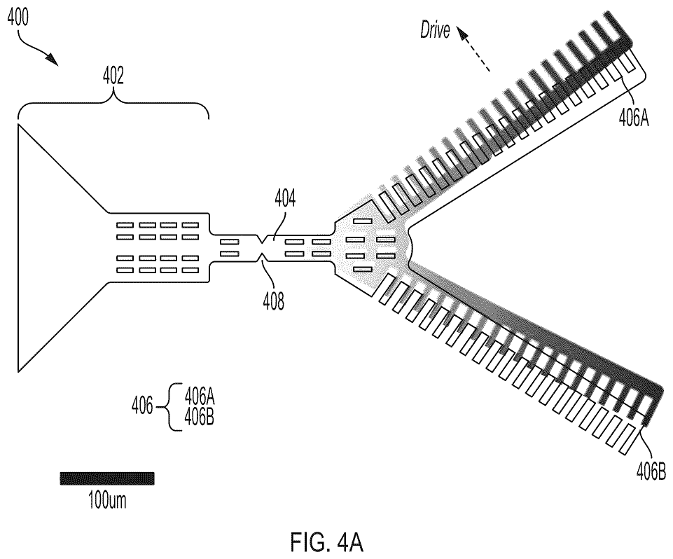

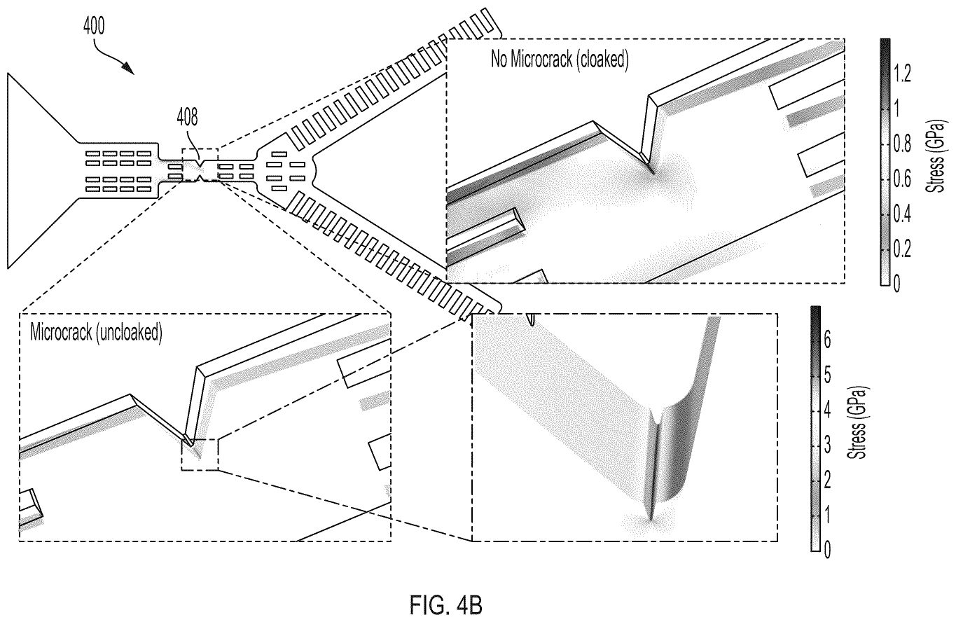

FIG. 4A is top view of a notch resonator (Nr) 400, according to some embodiments.

In some embodiments, the Nr 400 may be configured as described herein for the MEMS device 110a of FIG. 1A. For example, the Nr 400 has a first arm 406A and a second arm 406A that are supported by a body 402 in a manner similar to the arm 104 and the support 102, respectively.

In some embodiments, a MEMS device such as the notch resonator (Nr) 400 shown in FIG. 4A may be configured to localize stress on a particular region, which may give rise to mechanical fatigue. For example, the first arm 406A and the second arm 406B may be configured to displace with respect to the body 402 (e.g., together and/or individually, synchronously and/or asynchronously with one another) about a notch 408. In some embodiments, arms 406A and 406B may be configured to be displaced periodically, such as to produce mechanical oscillations that may translate into electrical oscillations. In the illustrated example, the Nr 400 includes a neck 404 joining the arms 406 to one another and to the notch 408, which may be configured as a pivot region for the arms 406 to displace with respect to the body 402. In some embodiments, the notch neck 404 may include a further pivot region for the arms 406A and 406B to displace relative to one another.

During mechanical oscillation of the arms 406, stress may be localized at a notch 408 and/or neck 404. Superimposed over the arms 406 and neck 404 in FIG. 4A is an intensity pattern illustrating displacement of the arms 406 during operation. In some embodiments, displacement of the arms 406A, 406B may exacerbate surface effects such as microcracks and/or dielectric charging of the notch 408 and/or neck 404. For example, cracks may expand due to localized stress when arms 406 are displaced. Alternatively or additionally, charges may become trapped within an oxide layer of the semiconductor substrate within the notch 408 and/or neck 404.

The Nr 400 is shown with a particular structure having a notch in a thick flexural beam that localizes stress over cyclic aging. The present disclosure recognizes that other structures benefit from the techniques described herein in connection with the Nr 400, as described further herein.

FIG. 4B is an analytical model of the Nr 400 of FIG. 4A illustrating localized stress on a microcrack in the surface of the Nr 400, according to some embodiments.

In some embodiments, FEA modeling of a MEMS device may be performed using scanning electron microscopy (SEM) images before and after fatigue of the device until failure. In some embodiments, FEA modeling may be used to identify appropriate coating layer material properties and/or dimensions for a particular implementation, such as described herein.

In some embodiments, finite element analysis (FEA) modeling of the Nr 400 and analytical modeling of the notch-localized stress may be developed using Equation (1), and Equation (2) below:

$${σ}_{notch} = {a}_{FEA} = \frac{\sqrt{2} {V}_{in - rm}}{\vert G ( j ω ) \vert ( {V}_{b} + {V}_{Surf} ) ( 2 π f ) \frac{dC}{d θ}} \qquad ( 1 )$$

$${i}_{0} = ( {V}_{b} + {V}_{Surf} ) \frac{\partial C}{\partial θ} {θ}_{0} ω = \frac{\sqrt{2} {V}_{RMS}}{G ( j ω )} \qquad ( 2 )$$

The analytical equation for stress in the notch is Equation (1), where α is derived from geometry-specific FEA model. This may be used to set the cyclic stress condition of the device during testing. The mass itself can be biased by V_{b}, and can instigate an oscillating current on the sense capacitor when resonating, which results in current i₀ in Equation (2).

In some embodiments, during operation of a MEMS device, charge buildup on surfaces may introduce sensor bias. For example, the presence of a bias potential can charge up surface oxides to a potential, V_{Surf}, creating drift in the imposed stress and sensor output. The input bias, V_{b}, can be used in modeling and in the device to extract V_{Surf}. Inverting the polarity periodically at different magnitudes can serve to measure V_{Surf}, which can be used to adjust the stress modeled in Equation (1).

In some embodiments, coating MEMS devices with coating layers materials that are electrically conductive may produce mechanically stable devices with extended lifetimes that are not affected by charging. According to some embodiments, the coating layers may be durable (high hardness and wear resistance), as disclosed herein and shown through favorable mechanical properties (e.g., Young's modulus). The coatings disclosed in some embodiments herein, when disposed at least in part within a crack, provide improved sensor performance because stress concentrations from cracks and imperfections are reduced (e.g., by an order of magnitude) compared to non-coated counterparts, and because electrical conductivity mitigates trapped surface charge buildup.

In some embodiments, a combination of FEA and analytical modeling may be used to identify appropriate coating layers to reduce mechanical and/or electrical fatigue. In one demonstrative example shown in FIG. 4B (“No Microcrack (cloaked)”), the Nr 400 may be modeled with no subcritical cracks as being actuated at an operating frequency (e.g., approximately 20 kHz), and the maximum stress on the notch 408 (1 GPa) may be below the fatigue limit for silicon (2.7 to 7.5 GPa). This modeling may represent a device with a coating layer that fills subcritical cracks and limits the maximum stress observed in operation.

In another demonstrative example shown in FIG. 4B (“Microcrack (uncloaked)”), a subcritical crack may be present in the notch 408, and the maximum simulated stress may be above the fracture limit (at 6 GPa), indicating a high likelihood of crack propagation and mechanical failure. This modeling may represent a device without a coating layer that fills subcritical cracks.

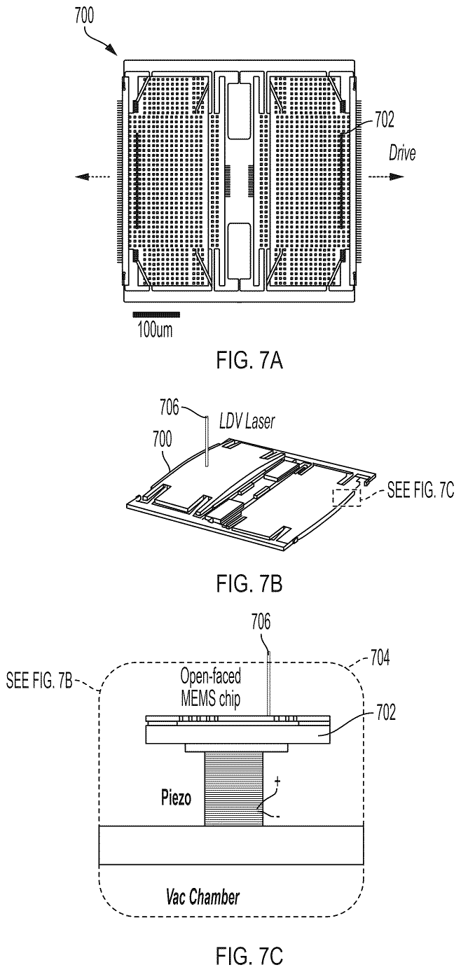

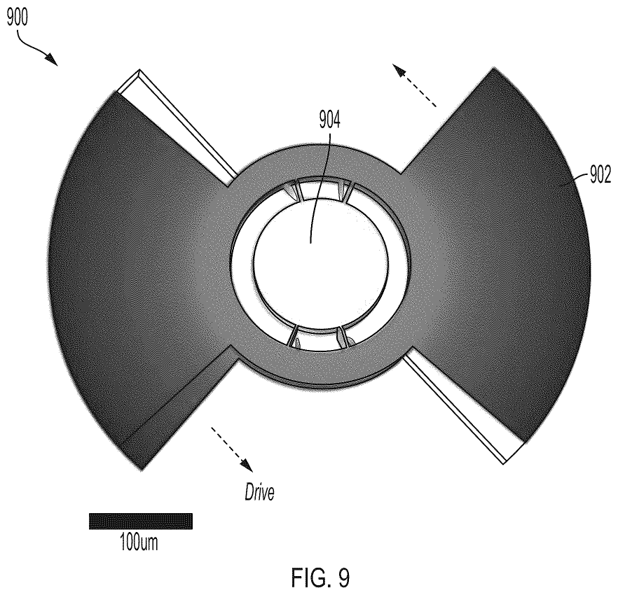

While the Nr 400 is used as one model to indicate appropriate coating materials and designs, and additional enhanced gyroscope designs (e.g., in FIGS. 7A-7C and FIG. 9) may further provide drift indications. Example devices that may be modeled in this manner include single-crystal silicon, 2-mask, high-yield silicon-on-insulator (SOI) wafer-based fabrication, among others. In some embodiments, drifting performance parameters may be monitored by a combination of laser Doppler vibrometers (LDV) and electrical charge amplification circuits. Modeling may further incorporate SEM/FIB of the device.

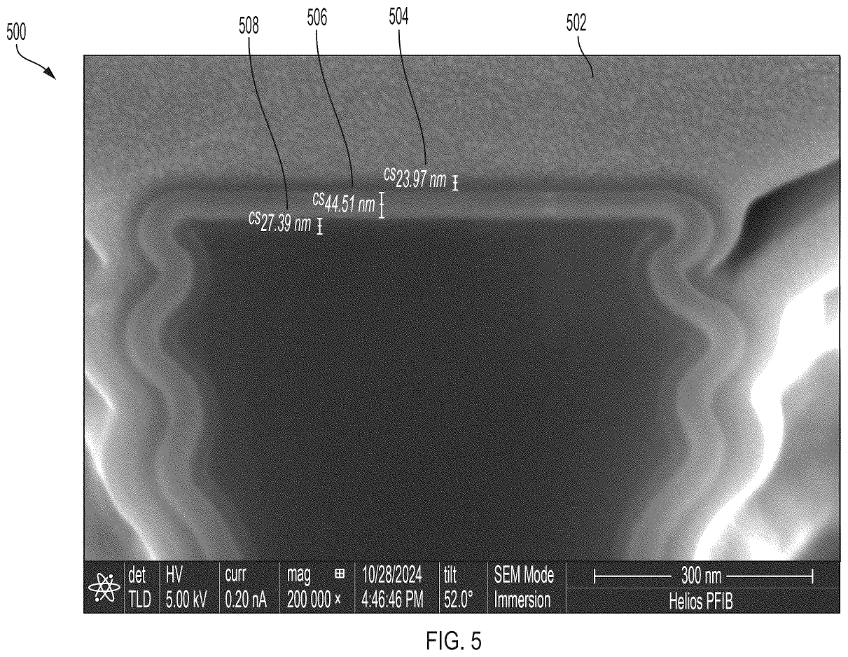

FIG. 5 is an SEM micrograph of multilayer coatings of silicon wells 500, according to some embodiments. In some embodiments, the silicon wells 500 may be part of a MEMS device, such as a support (e.g., 102), arm (104), rotor (e.g., 112), and/or bearing (e.g., 114). As shown in FIG. 5 and similar to the cross section 120 in FIG. 1C, the silicon wells 500 include a substrate 502 with a first coating layer 504, a second coating layer 506, and a third coating layer 508. In some embodiments, the first coating layer 504 may be a titanium nitride (TiN) layer with a thickness of 27.97 nm. In some embodiments, the second coating layer 506 may be an aluminum oxide (Al₂O₃) layer with a thickness of 44.51 nm. In some embodiments, the third coating layer 508 may be a TiN layer with a thickness of 27.39 nm.

FIG. 5 shows one example of three particular coating layers on a substrate. Additional examples of materials used as coating layers (e.g., first coating layer, second coating layer, third coating layer, etc.) are:

Diamond-like carbon (DLC): DLC thin films are amorphous carbon with properties such as high hardness, a Young's modulus four times higher than silicon, and resistant to corrosion and wear. By adjusting the sp²/sp³ bond ratio, the structure and properties may be fine-tuned to provide electrical conductivity (sp² bonds providing better electron movement due to pi bonds) and mechanical durability (sp³ bonds provide more stable coatings to shear stresses) which are important for longer lifetimes with minimal performance degradation.

Silicides: Silicides (e.g., metal silicides such as nickel (Ni)-, palladium (Pd)-, and platinum (Pt)-based silicides) have high hardness, are resistant to oxidation, and are low creep materials. Following silicide formation, excess metal may be etched off, leaving the coating only on the exposed Si surfaces.

Silicon carbide (SiC): SiC, a material with very high Young's modulus, has a fracture strength which is two times lower than the fatigue strength of silicon. SiC has been applied as coating on polycrystalline silicon double-clamped beams that underwent >100 billion contact cycles with little to no morphological changes compared to only the polycrystalline silicon devices.

Ruthenium (Ru): A heavily used electrical contact material for MEMS switches due to its high hardness and resistance to corrosion. Ruthenium oxide (RuO₂), formed by treating a metal surface with O₂ plasma, is electrically conductive with a sub-ohm contact resistance and has a Knoop hardness of approximately 20 GPa.

Tungsten (W): A material with high strength and thermal stability as well as an oxide which is conductive. Tungsten nucleates on silicon, offering selective deposition and it has been demonstrated to improve wear performance for MEMS micromachines, which improved wear performance by orders of magnitude.

Multilayer Coatings: Single layer coatings and multi-layers are developed and presented herein. Silicides may have similar Young's modulus to silicon, thus limiting stress concentrations and limiting cracking/delamination of the layers. The silicides may also diffuse into the silicon, preventing adhesion concern. However, the silicides have a thermal expansion mismatch with silicon, and so a conformal layer of Tungsten following the formation of the silicide can sandwich the silicide layer and constrain thermal expansion with a very stiff and stable expansion material.

The present disclosure recognizes that the type of material forming the coating layer, layer thickness, ratio of doping, roughness, grain size, electrical conductivity, crystallinity (crystal polytype), among other properties, may impact the performance, reliability, accuracy, etc. of the MEMS device. The present disclosure further recognizes that that material combinations, compatibility, adhesion, combinatorial material properties, etc. may also impact these properties.

Table 1 shows additional examples of materials that may be used in coating layers described herein and associated properties.

| | | | Thermal | |
|---|---|---|---|---|
| | | Young's | Expansion | |
| | Coating | Modulus | Coef. | |
| # | Material | [GPa] | [ppm/K] | Examples of Tunable Parameters |
| 1 | Diamond-Like | 200 to | 2.3 | Thickness: Deposition rate/gas flow and |
| | Carbon, | 500 can be | | temperature controls |
| | HDPCVD | varied with | | Ratio of sp²/sp³ (controlled by input gases): |
| | | bond ratio | | More sp² bonds gives properties like graphite |
| | | (sp²/sp³) | | (more electrically conductive) more sp³ gives |
| | | | | higher wear resistance but lowers electrical |
| | | | | conductivity |
| | | | | Hardness and Wear: Substrate temperature |
| | | | | during deposition |
| 2 | Nickel | 132 | 13 | Thickness: Initial metal thickness, anneal |
| | Silicide, ALD | | | temperature & time (controls diffusion) |
| | | | | Grain Size: Anneal temperature and duration. |
| | | | | Electrical Conductivity: Anneal temperature |
| | | | | and duration. |
| 3 | Palladium | 170 | 10.8 | Thickness: Initial metal thickness, anneal |
| | Silicide, ALD | | | temperature & duration (controls diffusion) |
| | | | | Grain Size: Anneal temperature and duration |
| | | | | Electrical Conductivity: Anneal temperature |
| | | | | and duration |
| 4 | Platinum | 210 | 10 | Thickness: Initial metal thickness, anneal |
| | Silicide, ALD | | | temperature & time (controls diffusion) |
| | | | | Grain Size (anneal temperature and time) |
| | | | | Electrical Conductivity (anneal temperature |
| | | | | and time) |
| 5 | SiC, | 440 | 2.3 (4H&6H | Thickness: Deposition rate/gas flow and |
| | HDPCVD | | SiC) to 4 (3C | temperature controls |
| | | | SiC) | Crystal Polytype: Controls electrical |
| | | | | conductivity, adjusted with pressure and |
| | | | | temperature |
| 6 | Ru, ALD | 447 | 6.4 | Thickness: Growth rate controlled by precursor |
| | | | | concentration, temperature, & time |
| | | | | Grain Size: Controls electrical conductivity |
| | | | | with anneal temperature & duration |
| | | | | Ruthenium Oxide Growth: O₂ plasma |
| | | | | ruthenium surface after deposition (more wear |
| | | | | resistance and corrosion resistance) and |
| | | | | electrically conductive. |
| 7 | W, ALD, | 340-405 | 4.4 | Thickness: Growth rate controlled by precursor |
| | PVD | | | concentration, temperature & time |
| | | | | Grain Size: Controls electrical conductivity |
| | | | | with anneal temperature & duration. |

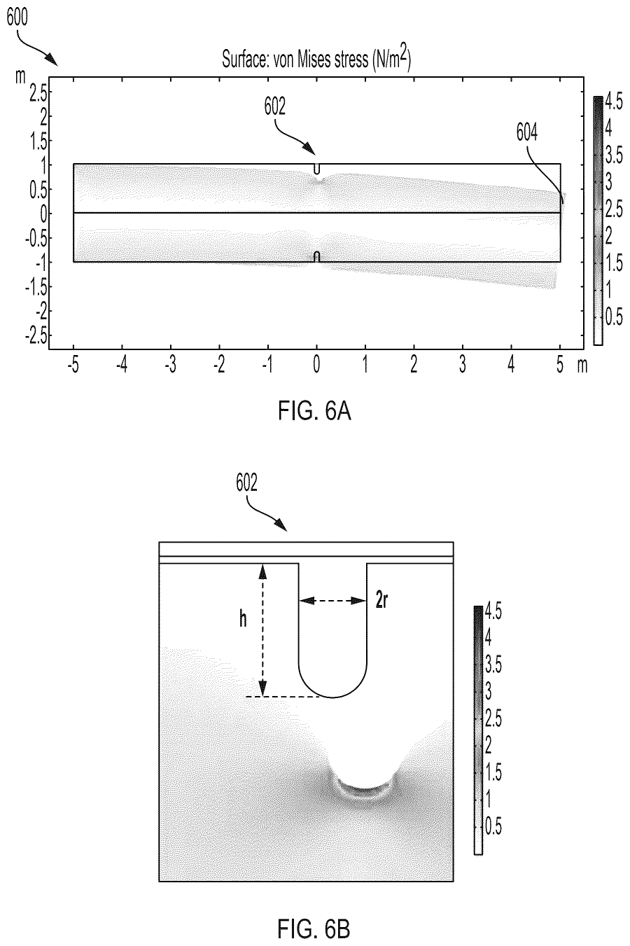

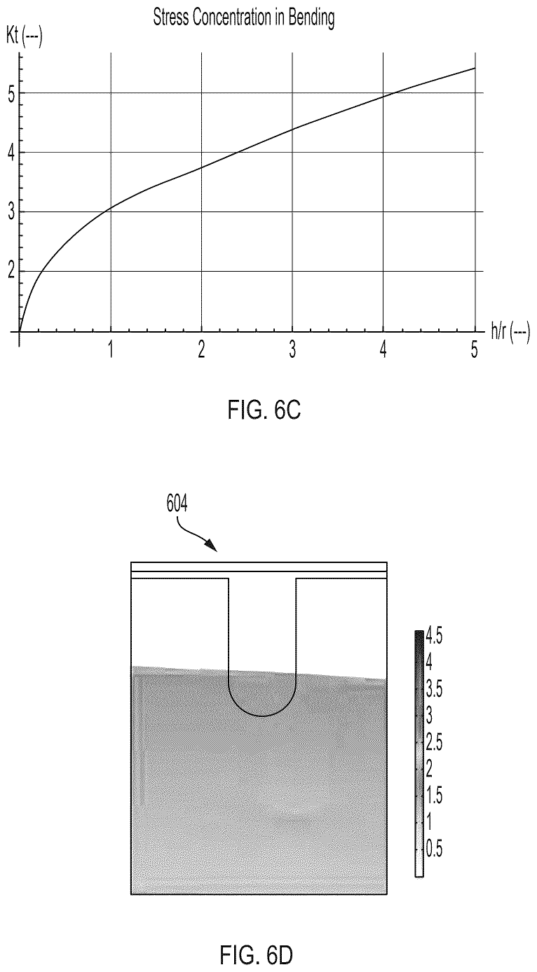

FIG. 6A is a Von Mises stress graph of a two-dimensional model of an uncoated flexure 600 built-in at a supported end with a pure torque applied at an opposite free end, with a surface crack 602 included in the top and bottom surfaces, according to some embodiments. FIG. 6B is a magnified view of the crack 602 in the flexure 600 of FIG. 6A with lines illustrating position of the flexure 600 prior to the application of torque, according to some embodiments. FIG. 6C is a graph illustrating the stress concentration factor (Kt) versus height/width ratio h/r of the crack 602 of FIG. 6B, according to some embodiments.

In some embodiments, the flexure 600 may be configured in the manner described herein for the arm 104 of FIG. 1A. For example, the flexure 600 includes a free end 604 that may be configured to displace with respect to a support. In the illustrated example, the flexure 600 is shown including a crack 602 that may localize stress as a weak point during displacement of flexure 600. In contrast to the example of FIG. 1A, the illustrated flexure 600 may not have any coating layers to indicate the impact of unmitigated stress on the crack 602 in the flexure 600.

The present disclosure recognizes that cracks are significantly susceptible to mechanical fatigue through stress concentration which may be mitigated by one or more coating layers. Without any coating layers and without taking the crack into consideration, the maximum stress experienced at any point of the flexure 600 may be low, such as 1 GPa. With a crack 602 whose height h is 4 times the radius r, the stress may be concentrated 4.5× on the crack 602. As shown in FIG. 6B, the crack 602 has a height h and a width 2r where r is the radius of the of the crack 602. As shown in FIG. 6C, one closed form solution model predicts a stress concentration of 5× on the crack 602.

FIG. 6D is a magnified view of the crack 602 on a simulated coated flexure having a palladium silicide (PdSi) coating layer having torque applied thereto, according to some embodiments. In some embodiments, the palladium silicide may have a Young's modulus of 140 GPa that is similar to a Young's modulus of 170 GPa for Silicon. As shown in FIG. 6D, the palladium silicide coating layer at least partially within the crack 602 may reduce the stress concentration factor on the crack 602 by 1.2×, an order of magnitude less than the uncoated case.

FIG. 7A is a top view of a tuning fork resonator (TFr) 700, according to some embodiments. FIG. 7B is a perspective view of the TFr 700 of FIG. 7A undergoing laser Doppler vibrometry (LDV), according to some embodiments. FIG. 7C is a side cross-sectional view of a mass 702 of the TFr 700 of FIG. 7A, according to some embodiments.

In some embodiments, the TFr 700 may include multiple masses 702 that may have semiconductor substrates with one or more coating layers as described herein. In some embodiments, the masses 702 may be configured for anti-phase displacement to provide differential sensing in a drive mode, which may advantageously benefit from common mode rejection. In some embodiments, the TFr 700 may have a resonant frequency of approximately 20 kHz for the drive mode, though other configurations are also envisioned.

In some embodiments, TFr 700 may be configured to operate as a gyroscope. For example, the TFr 700 may have a second mode in close proximity to the drive mode to couple in motion that is driven by angular rate. For example, the drive mode may have very stable position and velocity, and an angular rate from the second mode may indicate a Coriolis force by Equation (3) below. It may be advantageous to sense in both modes individually, such as to account for very subtle fabrication and environmental variations. The amplitude and phase of sense mode motion at the drive frequency are described by Equation (4) and Equation (5).

$${F}_{c} = {m}_{c} ( {v}_{x} \times {Ω}_{z} ) \qquad ( 3 )$$

$${y}_{0} = {Ω}_{z} \frac{{m}_{c} {ω}_{d}}{{m}_{s} {ω}_{s}^{2}} \frac{2 {x}_{0}}{\sqrt{{[ 1 - {( \frac{{ω}_{d}}{{ω}_{s}} )}^{2} ]}^{2} + {[ \frac{1 {ω}_{d}}{{Q}_{s} {ω}_{s}} ]}^{2}}} \qquad ( 4 )$$

$${φ}_{s} = - {tan}^{- 1} \frac{\frac{1 {ω}_{d}}{{Q}_{s} {ω}_{s}}}{1 - {( \frac{{ω}_{d}}{{ω}_{s}} )}^{2}} + {φ}_{d} \qquad ( 5 )$$

In some embodiments, the TFr 700 may be susceptible to dielectric charge buildup on the masses 702 that may still provide drift resulting in electrical aging. In some embodiments, an electrically conductive coating layer may be included on a semiconductor substrate of one or both masses 702, such as to reduce or eliminate dielectric charge buildup.

In some embodiments, the TFr 700 may further exhibit low (e.g., minimal) viscous damping in vacuum, which is also a major driver in drift, especially over temperature and age. In some embodiments, a devices may include a high mass (e.g., >1 milligram) and may be configured for large drive amplitudes (e.g., >400 millimeter/sec), which produce very high scale factors (Equation (3) above), amplifying their sensitivity to angular rate in a second mode.

In some embodiments, an accelerated fatigue model of open-face resonators such as the TFr 700 may use the Eyring equation shown as Equation (6) below (which can be reduced to the Arrhenius equation when constant m=0) where R(T) is the reaction rate dependent on temperature and a generalize form of Eyring equation includes a stress factor, with S representing stress, γ₀ is constant, γ₁ represents activation energy, and γ₂ is the stress-bias term.

$$R ( T ) = {γ}_{0} {T}^{m} exp [ \frac{- {E}_{a}}{{k}_{b} T} ] ⇒ R ( T , S ) = {γ}_{0} exp [ \frac{- {γ}_{1}}{{k}_{b} T} + {γ}_{2} S ] \qquad ( 6 )$$

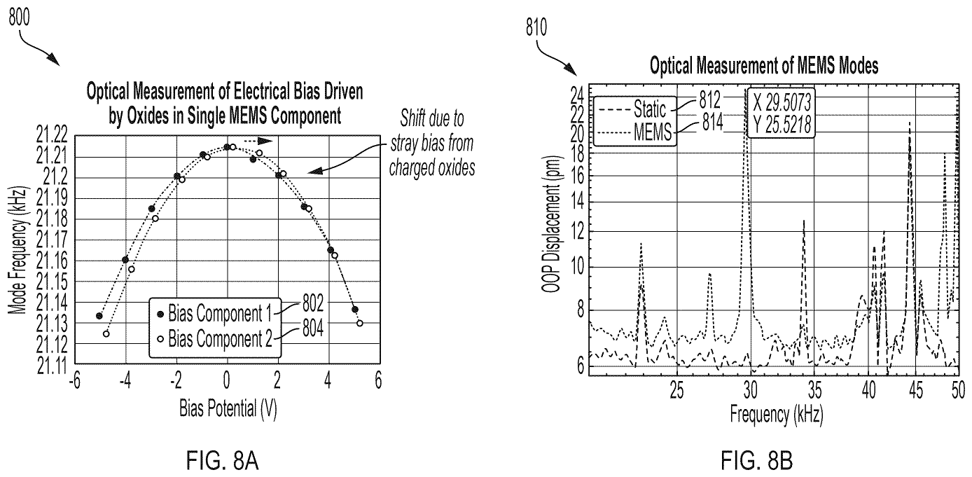

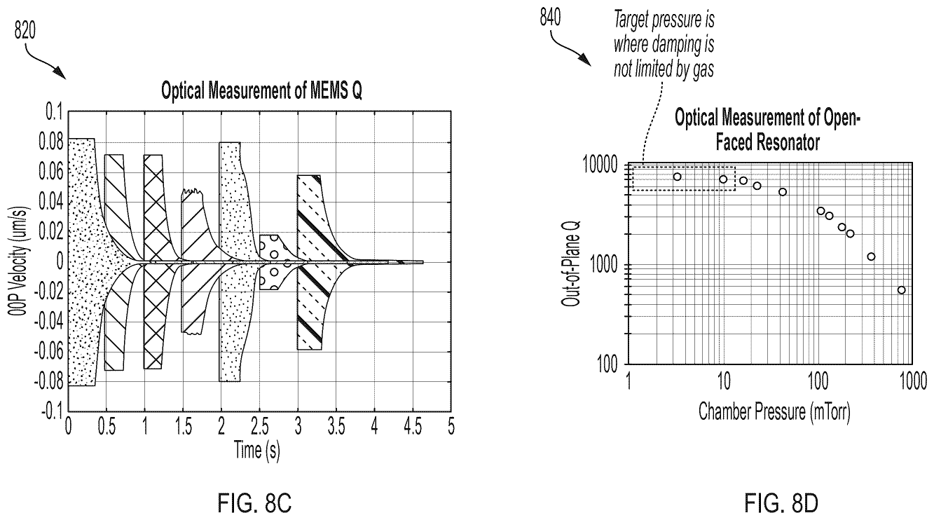

FIG. 8A is a graph 800 of optical measurements of surface charge induced-bias of TFr 700 of FIGS. 7A-7C, according to some embodiments. The graph 800 plots the changes of resonant mode frequency against changes in bias potential of the TFr 700. The results show misalignment of resonant frequency mode responses 802 and 804 between a first mass 702 and a second mass 702 of the TFr 700, respectively, which may result from bias due to charged oxides on the surfaces of the masses 702.

In some embodiments, a TFr 700 (e.g., having an open faced configuration) may be aged to demonstrate surface charge buildup over time using LDV by mounting the TFr 700 on a ceramic heater inside a vacuum chamber 704. A laser beam 706 may be incident on the TFr 700 while the resonant frequency and deflections of TFr 700 were monitored.

FIG. 8B is a graph 810 of measurements of MEMS modes of the TFr 700 of FIGS. 7A-7C, according to some embodiments. The graph 810 shows the out-of-plane (OOP) displacement spectrum of the TFr 700, illustrating the displacement amplitude as a function of drive frequency. The graph 810 shows a frequency spectrum for a static mode 812 and an active mode 814 of the TFr 700, which may be separated based on anti-phase as opposed to angular displacement as described herein.

FIG. 8C is a graph 820 of quality (Q)-factor measurements of the TFr 700 of FIGS. 7A-7C, according to some embodiments. The Q-factor measurements were obtained during a ringdown experiment of the TFr 700 brought to steady-state-oscillations at its OOP resonant frequency over the course of decaying resonance. The OOP velocity of the masses 702 is plotted over time.

FIG. 8D is a graph 840 of out of plane Q-factor of the TFr 700 of FIGS. 7A-7C over varying chamber pressure, according to some embodiments. In some embodiments, modulating chamber pressure of the TFr 700 validates behavior of the TFr 700 as shown in FIGS. 8A-8C as not being limited by pressure. For example, thermoelastic dissipation (TED) may include dissipation of energy resulting from irreversible flow of heat occurring due to periodic compression and tension of the TFr 700 during the LDV test, indicating a fundamental upper bound on the achievable Q-factor of the TFr 700. The graph 840 illustrates a decrease in OOP Q-factor as the pressure in the vacuum chamber 704 increases.

FIG. 9 is top view of a vibrating wheel resonator (VWr) 900, according to some embodiments.

In some embodiments, the VWr 900 may be configured as described herein for the MEMS device 110b of FIG. 1B. For example, the VWr 900 has a wheel 902 that may be rotatably coupled to a support via a bearing 904 such as described herein for the rotor 112 and the bearing 114, respectively. In some embodiments, the VWr 900 may have one or more coating layers such as described herein for the MEMS device 110b. For example, as shown in FIG. 9, intensity patterns indicate displacement of the wheel 902, which may indicate regions of localized stress that may be mitigated with an appropriate coating layer. Alternatively or additionally, wheel 902 may undergo electrical aging resulting in buildup of surface charge that may be mitigated with an appropriate coating layer.

In some embodiments, the VWr 900 may include two anti-phase masses (e.g., coupled to opposite ends of the wheel 902), such as to benefit from common mode rejection as described herein for the TFr 700. In some embodiments, the VWr 900 may exhibit low (e.g., minimize) viscous damping in vacuum, such as described herein for the TFr 700. In some embodiments, the VWr 900 may be configured as and/or within a gyroscope. In some embodiments, Equations (3)-(5) may be applied to model the behavior of the VWr 900.

The following aspects are further included as examples within the scope of the present disclosure.

Some aspects of the present disclosure relate to a micro-electro-mechanical systems (MEMS) device comprising: a semiconductor substrate; and first and second coating layers coated on the semiconductor substrate, wherein the first coating layer covers at least a portion of a surface of the semiconductor substrate, and wherein the second coating layer covers the first coating layer.

In some embodiments, the first coating layer and the semiconductor substrate have a Young's modulus within 5% of each other.

In some embodiments, the first coating layer has a Young's modulus of at least 130 Gigapascal (GPa) and no more than 450 GPa.

In some embodiments, the first coating layer is configured to limit stress concentration in the MEMS device.

In some embodiments, the first coating layer is configured to prevent delamination of the first and second coating layers.

In some embodiments, the first coating layer is configured to cover a plurality of cracks of the semiconductor substrate when the plurality of cracks are formed in the semiconductor substrate.

In some embodiments, the first coating layer is configured to cover at least 90% of the plurality of cracks.

In some embodiments, first coating layer has a thermal expansion coefficient between 2 parts-per-meter per degree Kelvin and 15 parts-per-meter per degree Kelvin.

In some embodiments, the first coating layer has a thickness between 0.1 nanometers and 500 nanometers.

In some embodiments, the first coating layer comprises carbon. In some embodiments, the first coating layer comprises diamond-like carbon. In some embodiments, the first coating layer comprises a transition metal. In some embodiments, the first coating layer comprises a metal silicide. In some embodiments, the metal silicide comprises nickel silicide. In some embodiments, the metal silicide comprises palladium silicide. In some embodiments, the metal silicide comprises platinum silicide. In some embodiments, the first coating layer comprises silicon carbide. In some embodiments, the first coating layer comprises a refractory metal. In some embodiments, the first coating layer comprises ruthenium. In some embodiments, the first coating layer comprises tungsten. In some embodiments, the first coating layer comprises a doped semiconductor layer.

In some embodiments, the second coating layer has a Young's modulus of at least 400 GPa.

In some embodiments, the second coating layer conforms to the first coating layer.

In some embodiments, the second coating layer is configured to constrain thermal expansion of the first coating layer.

In some embodiments, the second coating layer comprises a transition metal. In some embodiments, the second coating layer comprises a Group VI element. In some embodiments, the second coating layer comprises tungsten.

In some embodiments, the first coating layer and/or the second coating layer are configured to limit mechanical fatigue of the semiconductor substrate. In some embodiments, the first coating layer and/or the second coating layer are configured to limit electrical fatigue of the semiconductor substrate. In some embodiments, the first coating layer and/or the second coating layer are configured to limit bias drift of the MEMS device. In some embodiments, the first coating layer and/or the second coating layer are configured to limit surface charge buildup of the MEMS device.

In some embodiments, the semiconductor substrate comprises silicon. In some embodiments, the semiconductor substrate comprises monocrystalline silicon. In some embodiments, the semiconductor substrate comprises polycrystalline silicon. In some embodiments, the MEMS device is configured as a MEMS sensor. In some embodiments, the MEMS device is configured as an inertial sensor.

In some embodiments, the MEMS device further comprises: a first MEMS component comprising the semiconductor substrate and first coating layer and second coating layer; and a second MEMS component configured to move relative to the first MEMS component in response to an applied force.

Some aspects of the present disclosure relate to a gyroscope, comprising a MEMS device, the MEMS device comprising: a semiconductor substrate; and first and second coating layers coated on the semiconductor substrate, wherein the first coating layer covers at least a portion of a surface of the semiconductor substrate, and wherein the second coating layer covers the first coating layer.

Some aspects of the present disclosure relate to an accelerometer, comprising a MEMS device, the MEMS device comprising: a semiconductor substrate; and first and second coating layers coated on the semiconductor substrate, wherein the first coating layer covers at least a portion of a surface of the semiconductor substrate, and wherein the second coating layer covers the first coating layer.

Some aspects of the present disclosure relate to a magnetometer, comprising a MEMS device, the MEMS device comprising: a semiconductor substrate; and first and second coating layers coated on the semiconductor substrate, wherein the first coating layer covers at least a portion of a surface of the semiconductor substrate, and wherein the second coating layer covers the first coating layer.

Some aspects of the present disclosure relate to method of manufacturing a MEMS device, comprising: depositing the first coating layer on at least the portion of the substrate; and depositing the second coating layer on the first coating layer, wherein the MEMS device comprises: a semiconductor substrate; and first and second coating layers coated on the semiconductor substrate, wherein the first coating layer covers at least a portion of a surface of the semiconductor substrate, and wherein the second coating layer covers the first coating layer.

Having thus described several aspects and embodiments of the technology of the present disclosure, it is to be appreciated that various alterations, modifications, and improvements will readily occur to those of ordinary skill in the art. Such alterations, modifications, and improvements are intended to be within the spirit and scope of the technology described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The above-described embodiments may be implemented in any of numerous ways. One or more aspects and embodiments of the present disclosure involving the performance of processes or methods may utilize program instructions executable by a device (e.g., a computer, a processor, or other device) to perform, or control performance of, the processes or methods. In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various embodiments described above. The computer readable medium or media may be transportable, such that the program or programs stored thereon may be loaded onto one or more different computers or other processors to implement various ones of the aspects described above. In some embodiments, computer readable media may be non-transitory media.

The terms “program” or “software” are used herein in a generic sense to refer to any type of computer code or set of computer-executable instructions that may be employed to program a computer or other processor to implement various aspects as described above. Additionally, it should be appreciated that according to one aspect, one or more computer programs that when executed perform methods of the present disclosure need not reside on a single computer or processor, but may be distributed in a modular fashion among a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code may be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a Personal Digital Assistant (PDA), a smartphone or any other suitable portable or fixed electronic device.

Also, a computer may have one or more input and output devices. These devices may be used, among other things, to present a user interface. Examples of output devices that may be used to provide a user interface include printers or display screens for visual presentation of output and speakers or other sound generating devices for audible presentation of output. Examples of input devices that may be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “substantially,” “approximately,” and “about” may be used to mean within ±20% of a target value in some embodiments, within ±10% of a target value in some embodiments, within ±5% of a target value in some embodiments, and yet within ±2% of a target value in some embodiments. The terms “substantially,” “approximately,” and “about” may include the target value.

What is claimed is:

1. A micro-electro-mechanical systems (MEMS) device, comprising:
a semiconductor substrate; and
a first coating layer and a second coating layer that are on the semiconductor substrate,
wherein the first coating layer covers at least a portion of a surface of the semiconductor substrate, and wherein the second coating layer covers at least a portion of the first coating layer.

2. The MEMS device of claim 1, wherein the first coating layer and the semiconductor substrate have a Young's modulus within 5% of each other.

3. The MEMS device of claim 1, wherein the first coating layer has a first coefficient of thermal expansion, the second coating layer has a second coefficient of thermal expansion, and the second coefficient of thermal expansion is closer than the first coefficient of thermal expansion to a coefficient of thermal expansion of the semiconductor substrate.

4. The MEMS device of claim 1, wherein the first coating layer includes silicide and the second coating layer includes a transition metal.

5. The MEMS device of claim 1, wherein the first coating layer includes silicide and the semiconductor substrate includes at least a portion of the silicide below the surface.

6. The MEMS device of claim 1, wherein the first coating layer is configured to distribute stress localized on a region of the semiconductor substrate over a larger area of the semiconductor substrate than without the first coating layer.

7. The MEMS device of claim 1, wherein the first coating layer is disposed at least in part within a crack in the surface of the semiconductor substrate.

8. The MEMS device of claim 1, wherein the first coating layer and/or the second coating layer includes electrically conductive material.

9. The MEMS device of claim 8, wherein the MEMS device comprises an electrode coupled to the semiconductor substrate, and the electrically conductive material of the first coating layer and/or the second coating layer is electrically isolated from the electrode.

10. The MEMS device of claim 1, wherein the first coating layer and/or the second coating layer has a thickness between 0.1 nanometers (nm) and 500 nm.

11. A micro-electro-mechanical systems (MEMS) device, comprising:
a support; and
a MEMS component coupled to the support that is displaceable in response to applied force and includes an electrode,
wherein the MEMS component comprises a semiconductor substrate and a coating layer on a surface of the semiconductor substrate.

12. The MEMS device of claim 11, wherein the coating layer is disposed at least in part within a crack in the surface of the semiconductor substrate.

13. The MEMS device of claim 11, wherein the coating layer includes electrically conductive material that is electrically isolated from the electrode.

14. The MEMS device of claim 11, wherein the coating layer includes silicide and the semiconductor substrate includes at least a portion of the silicide below the surface.

15. The MEMS device of claim 11, wherein the coating layer is a first coating and the MEMS device further comprises a second coating on the first coating, and the second coating includes metal.

16. The MEMS device of claim 15, wherein the second coating includes tungsten.

17. The MEMS device of claim 11, wherein the coating layer has a thickness between 0.1 nanometers (nm) and 500 nm.

18. The MEMS device of claim 11, wherein the coating layer and the semiconductor substrate have a Young's modulus within 5% of each other.

19. A MEMS-based gyroscope including the MEMS device of claim 11, wherein the MEMS component comprises a rotor, a flexure, and/or a mass.

20. A MEMS-based sensor system comprising the MEMS device of claim 11 and circuitry electrically coupled to the electrode and configured to drive the MEMS device with an oscillating drive signal.
